(19) United States
(12) Patent Application Publication
(10) Pub. No.: US 2023/0129748 A1
(43) Pub. Date: Apr. 27, 2023

(54) TRANSPARENT ELECTROCONDUCTIVE FILM

(71) Applicant: NITTO DENKO CORPORATION, Ibaraki-shi, Osaka (JP)

(72) Inventors: Nozomi Fujino, Osaka (JP); Taisuke Karasuda, Osaka (JP)

(73) Assignee: NITTO DENKO CORPORATION, Ibaraki-shi, Osaka (JP)

(21) Appl. No.: 17/912,187

(22) PCT Filed: Mar. 18, 2021
(86) PCT No.: PCT/JP2021/011152

§ 371 Date: Sep. 16, 2022

(30) Foreign Application Priority Data
Mar. 19, 2020 (JP) 2020-049864
Apr. 20, 2020 (JP) 2020-074853
Apr. 20, 2020 (JP) 2020-074854
Aug. 7, 2020 (JP) 2020-134832
Aug. 7, 2020 (JP) 2020-134833
Aug. 21, 2020 (JP) 2020-140241
Dec. 2, 2020 (JP) 2020-200421
Dec. 2, 2020 (JP) 2020-200422

(51) Int. Cl. H01B 5/14; H01B 1/06

(52) U.S. Cl. CPC H01B 5/14; H01B 1/06

(57) ABSTRACT

A transparent electroconductive film (X) includes a resin film (11) and a light-transmitting electroconductive layer (20) in this order in a thickness direction (D). The light-transmitting electroconductive layer (20) has a first compressive residual stress in a first in-plane direction orthogonal to the thickness direction (D), and has a second compressive residual stress less than the first compressive residual stress in a second in-plane direction orthogonal to each of the thickness direction (D) and the first in-plane direction. A ratio of the second compressive residual stress to the first compressive residual stress is 0.82 or less.

### TECHNICAL FIELD

The present invention relates to a transparent electroconductive film.

### BACKGROUND ART

Conventionally, a transparent electroconductive film sequentially including a transparent substrate film and a transparent electroconductive layer (light-transmitting electroconductive layer) in the thickness direction has been known. The light-transmitting electroconductive layer is used as, for example, a conductor film for forming a pattern of a transparent electrode in various devices such as a liquid crystal display, a touch panel, and an optical sensor. The light-transmitting electroconductive layer may be used as an antistatic layer included in a device. The light-transmitting electroconductive layer is formed by, for example, depositing an electroconductive oxide on a resin-made substrate film by a sputtering method. In the sputtering method, conventionally, an inert gas such as argon has been used as a sputtering gas for colliding with a target (a film formation material supply) to sputter atoms on a target surface. The technique relating to the transparent electroconductive film is described in, for example, Patent Document 1 below.

### CITATION LIST

### Patent Document

Patent Document 1: Japanese Unexamined Patent Publication No. 5-334924

### SUMMARY OF THE INVENTION

### Problem to be Solved by the Invention

The process of producing the transparent electroconductive film may involve a method of forming an amorphous light-transmitting electroconductive layer on the substrate film, and heating the light-transmitting electroconductive layer to convert the amorphous layer to a crystalline layer. In this case, the higher the heating temperature in the crystallization process is, the smaller the resistance value of the crystalline light-transmitting electroconductive layer thus formed tends to be.

On the other hand, since the transparent electroconductive film includes a resin substrate film, excessively high heating temperature in the crystallization process causes various problems (e.g., cracking of the light-transmitting electroconductive layer) resulting from dimensional change or the like in the resin substrate film. When excessive increase in the heating temperature is suppressed in the crystallization process to avoid such problems, the formed crystalline light-transmitting electroconductive layer may not have a sufficiently small resistance value. When the transparent electroconductive film having such light-transmitting electroconductive layer undergoes the heating process in a process of manufacturing a device or the like including such film, the resistance value of the light-transmitting electroconductive layer of the transparent electroconductive film may change (e.g., be reduced). The changes in the resistance value of the light-transmitting electroconductive layer in the transparent electroconductive film after the manufacturing are not preferred.

The present invention provides a transparent electroconductive film suitable for suppressing after-the-fact changes in the resistance value of the light-transmitting electroconductive layer.

### Means for Solving the Problem

The present invention [1] includes a transparent electroconductive film including a transparent resin substrate and a light-transmitting electroconductive layer in this order in a thickness direction, wherein the light-transmitting electroconductive layer has a first compressive residual stress in a first in-plane direction orthogonal to the thickness direction, and a second compressive residual stress less than the first compressive residual stress in a second in-plane direction orthogonal to each of the thickness direction and the first in-plane direction, and a ratio of the second compressive residual stress to the first compressive residual stress is 0.82 or less.

The present invention [2] includes the transparent electroconductive film described in [1], in which the light-transmitting electroconductive layer contains krypton.

The present invention [3] includes the transparent electroconductive film described in [1] or [2], wherein the transparent resin substrate is not adjacent to a glass substrate.

The present invention [4] includes the transparent electroconductive film described in any one of the above-described [1] to [3], wherein the light-transmitting electroconductive layer has a specific resistance of less than 2.2×10⁻⁴ Ω·cm.

The present invention [5] includes the transparent electroconductive film described in any one of the above-described [1] to [4], wherein the light-transmitting electroconductive layer has a thickness of 100 nm or more.

### Effects of the Invention

In the transparent electroconductive film of the present invention, the light-transmitting electroconductive layer has a first compressive residual stress in a first in-plane direction, and a second compressive residual stress less than the first compressive residual stress in a second in-plane direction orthogonal to the first in-plane direction, and a ratio of the second compressive residual stress to the first compressive residual stress is 0.82 or less. Therefore, the transparent electroconductive film of the present invention is suitable for suppressing after-the-fact changes in the resistance value of the light-transmitting electroconductive layer.

### BRIEF DESCRIPTION OF THE DRAWINGS

FIG. 1 is a schematic cross-sectional view of one embodiment of a transparent electroconductive film according to the present invention.

FIGS. 2A and 2B are each a schematic cross-sectional view of a modification of the transparent electroconductive film according to the present invention: FIG. 2A represents a case where the light-transmitting electroconductive layer includes a first region and a second region in this order from a transparent resin substrate side, and FIG. 2B represents a case where the light-transmitting electroconductive layer includes the second region and the first region in this order from the transparent resin substrate side.

FIGS. 3A to 3D represent a method of producing the transparent electroconductive film shown in FIG. 1: FIG. 3A represents a step of preparing a resin film, FIG. 3B represents a step of forming a functional layer on the resin film, FIG. 3C represents a step of forming a light-transmitting electroconductive layer on the functional layer, and FIG. 3D represents a step of crystallizing the light-transmitting electroconductive layer.

FIG. 4 represents a case where the light-transmitting electroconductive layer of the transparent electroconductive film shown in FIG. 1 is patterned.

FIG. 5 is a graph showing a relationship between an amount of oxygen introduced when the light-transmitting electroconductive layer is formed by a sputtering method and a specific resistance of the formed light-transmitting electroconductive layer.

### DESCRIPTION OF THE EMBODIMENTS

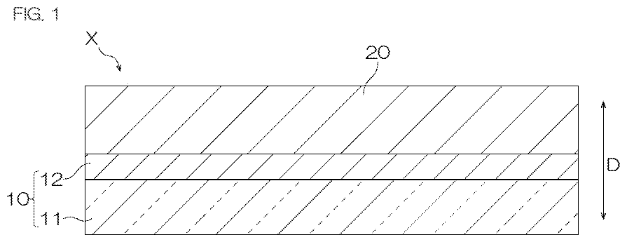

FIG. 1 is a schematic cross-sectional view of a transparent electroconductive film X as one embodiment of the transparent electroconductive film according to the present invention. The transparent electroconductive film X includes a transparent resin substrate 10 and a light-transmitting electroconductive layer 20 in this order toward one side in a thickness direction D. The transparent electroconductive film X has a shape extending in a direction (plane direction) orthogonal to the thickness direction D. The transparent electroconductive film X is one element provided in a touch sensor device, a light control element, a photoelectric conversion element, a hot wire control member, an antenna member, an electromagnetic wave shielding member, a heater member, an illuminating device, an image display device, and the like.

In the present embodiment, the transparent resin substrate 10 includes a resin film 11 and a functional layer 12 in this order toward one side in the thickness direction D. The transparent resin substrate 10 has a shape extending in a direction (plane direction) orthogonal to the thickness direction D. Specifically, the transparent resin substrate 10 extends in a first in-plane direction orthogonal to the thickness direction D, and extends in a second in-plane direction orthogonal to each of the thickness direction D and the first in-plane direction. In the present embodiment, the transparent resin substrate 10 has a lengthy shape long in the first in-plane direction. In the present embodiment, the first in-plane direction is a resin flow direction (MD direction) in the process of producing the resin film 11 included in the transparent resin substrate 10, and the second in-plane direction is a width direction (TD direction) orthogonal to each of the resin flow direction and the thickness direction D. In addition, in the present embodiment, the first in-plane direction is a direction in which a rate of dimensional change by heating (maximum thermal shrinkage coefficient) of the transparent resin substrate 10 is maximum, and the second in-plane direction is a direction orthogonal to each of the first in-plane direction and the thickness direction D. The direction in which the rate of dimensional change by heating of the transparent resin substrate 10 is maximum can be determined by defining an axis extending in an arbitrary direction in the transparent resin substrate 10 as a reference axis (0°), and measuring, in axial directions in 15° increments based on the reference axis, the rate of dimensional change between before and after heating. The heating temperature to determine the rate of dimensional change by heating can be set to a suitable temperature according to the heat resistant temperature of the resin film 11. When the resin film 11 is a polyethylene terephthalate (PET), for example, a heating temperature of 150° C. can be adopted, and when it is a cycloolefin polymer, for example, a heating temperature of 110° C. can be adopted. A time for the heating is, for example, 1 hour.

The resin film 11 is a transparent resin film having flexibility. The resin film 11 has a shape extending in a direction (plane direction) orthogonal to the thickness direction D. Specifically, the resin film 11 extends in the first in-plane direction orthogonal to the thickness direction D, and extends in the second in-plane direction orthogonal to each of the thickness direction D and the first in-plane direction. In the present embodiment, the resin film 11 has a lengthy shape long in the first in-plane direction. In the present embodiment, the first in-plane direction is the MD direction described above, and the second in-plane direction is the TD direction described above.

Examples of the material of the resin film 11 include polyester resin, polyolefin resin, acrylic resin, polycarbonate resin, polyether sulfone resin, polyarylate resin, melamine resin, polyamide resin, polyimide resin, cellulose resin, and polystyrene resin. Examples of the polyester resin include polyethylene terephthalate (PET), polybutylene terephthalate, and polyethylene naphthalate. Examples of the polyolefin resin include polyethylene, polypropylene, and cycloolefin polymer. Examples of the acrylic resin include polymethacrylate. As the material of the resin film 11, preferably, a polyester resin is used, more preferably, a PET is used, for example, in view of transparency and strength.

A functional layer 12-side surface of the resin film 11 may be surface-modified in a surface modification treatment. Examples of the surface modification treatment include corona treatment, plasma treatment, ozone treatment, primer treatment, glow treatment, and coupling agent treatment.

The resin film 11 has a thickness of preferably 1 μm or more, more preferably 10 μm or more, even more preferably 30 μm or more. The resin film 11 has a thickness of preferably 300 μm or less, more preferably 200 μm or less, even more preferably 100 μm or less, particularly preferably 75 μm or less. These configurations relating to the thickness of the resin film 11 are suitable for ensuring the handleability of the transparent electroconductive film X.

The resin film 11 has a total light transmittance (JIS K 7375-2008) of preferably 60% or more, more preferably 80% or more, even more preferably 85% or more. This configuration is suitable for ensuring the transparency required for the transparent electroconductive film X when the transparent electroconductive film X is provided in a touch sensor device, a light control element, a photoelectric conversion element, a hot wire control member, an antenna member, an electromagnetic wave shielding member, a heater member, an illuminating device, an image display device, and the like. The resin film 11 has a total light transmittance of, for example, 100% or less.

In the present embodiment, the functional layer 12 is located on one surface in the thickness direction D of the resin film 11. In the present embodiment, the functional layer 12 is a hard coat layer for preventing a scratch from being formed on an exposed surface (upper surface in FIG. 1) of the light-transmitting electroconductive layer 20.

The hard coat layer is a cured product of a curable resin composition. Examples of the resin contained in the curable resin composition include polyester resin, acrylic resin, urethane resin, amide resin, silicone resin, epoxy resin, and melamine resin. Examples of the curable resin composition include an ultraviolet curing type resin composition and a thermosetting type resin composition. As the curable resin composition, an ultraviolet curing type resin composition is preferably used in view of serving to improve production efficiency of the transparent electroconductive film X because it can be cured without heating at a high temperature. As the ultraviolet curing type resin composition, specifically, a composition for forming a hard coat layer described in Japanese Unexamined Patent Publication No. 2016-179686 is used.

A light-transmitting electroconductive layer 20-side surface of the functional layer 12 may be surface-modified in a surface modification treatment. Examples of the surface modification treatment include corona treatment, plasma treatment, ozone treatment, primer treatment, glow treatment, and coupling agent treatment.

The functional layer 12 serving as the hard coat layer has a thickness of preferably 0.1 μm or more, more preferably 0.5 μm or more, even more preferably 1 μm or more. This configuration is suitable for allowing the light-transmitting electroconductive layer 20 to have sufficient scratch resistance. The functional layer 12 serving as the hard coat layer has a thickness of preferably 10 μm or less, more preferably 5 μm or less, even more preferably 3 μm or less in view of ensuring the transparency of the functional layer 12.

The transparent resin substrate 10 has a thickness of preferably 1 μm or more, more preferably 10 μm or more, even more preferably 15 μm or more, particularly preferably 30 μm or more. The transparent resin substrate 10 has a thickness of preferably 310 μm or less, more preferably 210 μm or less, even more preferably 110 μm or less, particularly preferably 80 μm or less. These configurations relating to the thickness of the transparent resin substrate 10 are suitable for ensuring the handleability of the transparent electroconductive film X.

The transparent resin substrate 10 has a total light transmittance (JIS K 7375-2008) of preferably 60% or more, more preferably 80% or more, even more preferably 85% or more. This configuration is suitable for ensuring the transparency required for the transparent electroconductive film X when the transparent electroconductive film X is provided in a touch sensor device, a light control element, a photoelectric conversion element, a hot wire control member, an antenna member, an electromagnetic wave shielding member, a heater member, an illuminating device, an image display device, and the like. The transparent resin substrate 10 has a total light transmittance of, for example, 100% or less.

In the present embodiment, the transparent electroconductive film X does not include a glass substrate. The transparent resin substrate 10 is not adjacent to a glass substrate. These configurations are suitable for ensuring the flexibility of the transparent electroconductive film X.

In the present embodiment, the light-transmitting electroconductive layer 20 is located on one surface in the thickness direction D of the resin film 11. The light-transmitting electroconductive layer 20 is a crystalline film having both optical transparency and conductivity.

The light-transmitting electroconductive layer 20 is a layer formed of a light-transmitting electroconductive material. The light-transmitting electroconductive material contains, for example, an electroconductive oxide as a main component.

Examples of the electroconductive oxide include metal oxides containing at least one kind of metal or metalloid selected from the group consisting of In, Sn, Zn, Ga, Sb, Ti, Si, Zr, Mg, Al, Au, Ag, Cu, Pd, and W. Specific examples of the electroconductive oxide include an indium-containing electroconductive oxide and an antimony-containing electroconductive oxide. Examples of the indium-containing electroconductive oxide include an indium tin composite oxide (ITO), an indium zinc composite oxide (IZO), an indium gallium composite oxide (IGO), and an indium gallium zinc composite oxide (IGZO). Examples of the antimony-containing electroconductive oxide include an antimony tin composite oxide (ATO). In view of realizing high transparency and good electrical conductivity, as the electroconductive oxide, preferably an indium-containing electroconductive oxide is used, more preferably, an ITO is used. Such ITO may contain a metal or a metalloid other than In and Sn in an amount less than the content of each of In and Sn.

When an ITO is used as the electroconductive oxide, the ratio of the content of tin oxide (SnO₂) to the total content of indium oxide (In₂O₃) and tin oxide in the ITO is preferably 0.1% by mass or more, more preferably 3% by mass or more, even more preferably 5% by mass or more, particularly preferably 7% by mass or more. The ratio of the number of tin atoms to the number of indium atoms (number of tin atoms/number of indium atoms) in the ITO used is preferably 0.001 or more, more preferably 0.03 or more, even more preferably 0.05 or more, particularly preferably 0.07 or more. These configurations are suitable for ensuring durability of the light-transmitting electroconductive layer 20. In addition, the ratio of the tin oxide (SnO₂) to the total content of indium oxide (In₂O₃) and tin oxide in the ITO used, preferably 15% by mass or less, more preferably 13% by mass or less, even more preferably 12% by mass or less. The ratio of the number of tin atoms to the number of indium atoms (number of tin atoms/number of indium atoms) in the ITO used is preferably 0.16 or less, more preferably 0.14 or less, even more preferably 0.13 or less. These configurations are suitable for obtaining the light-transmitting electroconductive layer 20 that is easily crystallized by heating. The ratio of the number of tin atoms to the number of indium atoms in the ITO is determined by, for example, specifying ratios of the indium atom and the tin atom present in an object to be measured by X-ray photoelectron spectroscopy. The above-mentioned content ratio of the tin oxide in the ITO is determined from, for example, such specified ratios of the indium atom and the tin atom present therein. The above-mentioned content ratio of tin oxide in the ITO may also be judged from the content ratio of tin oxide (SnO₂) in an ITO target used during sputtering film formation.

The light-transmitting electroconductive layer 20 may contain rare gas atoms. Examples of the rare gas atom include argon (Ar), krypton (Kr), and xenon (Xe). In the present embodiment, the rare gas atoms in the light-transmitting electroconductive layer 20 are derived from rare gas atoms used as a sputtering gas in a sputtering method to be described later for forming the light-transmitting electroconductive layer 20. In the present embodiment, the light-transmitting electroconductive layer 20 is a film (sputtered film) formed by the sputtering method.

The content ratio of the rare gas atom (e.g., ratio of the total content of Kr and Ar) in the light-transmitting electroconductive layer 20 is preferably 1.2 atomic % or less, more preferably 1.1 atomic % or less, even more preferably 1.0 atomic % or less, even more preferably 0.8 atomic % or less, even more preferably 0.5 atomic % or less, even more preferably 0.4 atomic % or less, even more preferably 0.3 atomic % or less, even more preferably 0.2 atomic % or less, entirely in the thickness direction D. This configuration is suitable for forming large crystal grains that achieve good crystal growth when an amorphous light-transmitting electroconductive layer (light-transmitting electroconductive layer 20′ to be described later) is crystallized by heating in the process of producing the transparent electroconductive film X, and thus, suitable for obtaining the light-transmitting electroconductive layer 20 having low resistance (the larger the crystal grains in the light-transmitting electroconductive layer 20, the lower the resistance of the light-transmitting electroconductive layer 20). The light-transmitting electroconductive layer 20 includes a region in which the content ratio of the rare gas atom is, for example, 0.0001 atomic % or more at least partially in the thickness direction D. The content ratio of the rare gas atom in the light-transmitting electroconductive layer 20 is preferably, for example, 0.0001 atomic % or more entirely in the thickness direction D.

The presence or absence of and the content of the rare gas atom such as Kr in the light-transmitting electroconductive layer 20 are identified by, for example, Rutherford backscattering spectrometry to be described later regarding Examples. The presence or absence of the rare gas atoms such as Kr in the light-transmitting electroconductive layer 20 is identified by, for example, X-ray fluorescence analysis to be described later regarding to Examples. In the following case, a light-transmitting electroconductive layer is judged to include a region in which the content ratio of the rare gas atom such as Kr is 0.0001 atomic % or more: the rare gas atom content in a light-transmitting electroconductive layer to be analyzed is less than a detection limit value (lower limit value) and cannot be quantified in Rutherford backscattering spectrometry, and the presence of the rare gas atom in the light-transmitting electroconductive layer is identified by X-ray fluorescence analysis.

In view of reducing production cost of the transparent electroconductive film X, the light-transmitting electroconductive layer 20 preferably contains no Xe.

In view of achieving good crystal growth to form large crystal grains when the light-transmitting electroconductive layer 20 is formed in the process of producing the transparent electroconductive film X, the light-transmitting electroconductive layer 20 preferably contains Kr, more preferably contains Kr alone, as the rare gas atoms. The configuration suitable for forming large crystal grains in the light-transmitting electroconductive layer 20 is suitable for reducing resistance of the light-transmitting electroconductive layer 20. The configuration suitable for forming large crystal grains in the light-transmitting electroconductive layer 20 is suitable for reducing a net compressive residual stress in the formed light-transmitting electroconductive layer 20.

The light-transmitting electroconductive layer 20 includes a region in which a content ratio of Kr is preferably 1.0 atomic % or less, more preferably 0.7 atomic % or less, even more preferably 0.5 atomic % or less, even more preferably 0.3 atomic % or less, even more preferably 0.2 atomic % or less, even more preferably less than 0.1 atomic %, partially in the thickness direction D. The Kr content ratio in the region is, for example, 0.0001 atomic % or more. Preferably, the light-transmitting electroconductive layer 20 satisfies such Kr content ratio entirely in the thickness direction D. Specifically, the content ratio of Kr in the light-transmitting electroconductive layer 20 is preferably less than 1.0 atomic %, more preferably 0.7 atomic % or less, even more preferably 0.5 atomic % or less, even more preferably 0.3 atomic % or less, even more preferably 0.2 atomic % or less, even more preferably less than 0.1 atomic %, entirely in the thickness direction D. These configurations are suitable for achieving good crystal growth to form large crystal grains when an amorphous light-transmitting electroconductive layer (light-transmitting electroconductive layer 20′ to be described later) is crystallized by heating in the process of producing the transparent electroconductive film X, and thus, suitable for obtaining the light-transmitting electroconductive layer 20 having low resistance (the larger the crystal grains in the light-transmitting electroconductive layer 20, the lower the resistance of the light-transmitting electroconductive layer 20).

The content ratio of Kr in the light-transmitting electroconductive layer 20 may be non-uniform in the thickness direction D. For example, in the Kr-containing region, the Kr content ratio may gradually increase or decrease in the thickness direction D depending on the distance from the transparent resin substrate 10. Alternatively, the light-transmitting electroconductive layer 20 may have a partial region on the transparent resin substrate 10 side in which the Kr content ratio gradually increases in the thickness direction D depending on the distance from the transparent resin substrate 10, and a partial region on the opposite side to the transparent resin substrate 10 in which the Kr content ratio gradually decreases in the thickness direction D depending on the distance from the transparent resin substrate 10. Alternatively, a partial region on the transparent resin substrate 10 side in which the Kr content ratio gradually decreases in the thickness direction D depending on the distance from the transparent resin substrate 10, and a partial region on the opposite side to the transparent resin substrate 10 in which the Kr content ratio gradually increases in the thickness direction D depending on the distance from the transparent resin substrate 10.

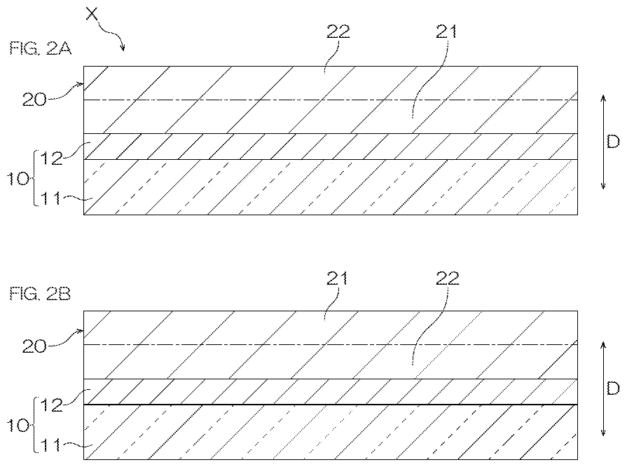

As exemplified in FIG. 2, the light-transmitting electroconductive layer 20 may contain Kr in a partial region in the thickness direction D. FIG. 2A represents a case where the light-transmitting electroconductive layer 20 includes the first region 21 and the second region 22 in this order from the transparent resin substrate 10 side. The first region 21 contains Kr. The second region 22 contains no Kr but contains, for example, rare gas atoms other than Kr. FIG. 2B represents a case where the light-transmitting electroconductive layer 20 includes the second region 22 and the first region 21 in this order from the transparent resin substrate 10 side. In FIGS. 2A and 2B, a boundary between the first region 21 and the second region 22 is drawn in phantom line. However, where the first region 21 and the second region 22 are not significantly different in terms of the composition other than a very small amount of rare gas atoms contained, or the like, the boundary between the first region 21 and the second region 22 may not be able to be discriminated.

In view of reducing a specific resistance of the light-transmitting electroconductive layer 20 while reducing the compressive residual stress therein, the light-transmitting electroconductive layer 20 includes the first region 21 (Kr-containing region) and the second region (Kr-free region) in this order from the transparent resin substrate 10 side.

When the light-transmitting electroconductive layer 20 includes the first region 21 and the second region 22, the proportion of the thickness of the first region 21 with respect to the total thickness of the first region 21 and the second region 22 is preferably 1% or more, more preferably 20% or more, even more preferably 30% or more, especially preferably 40% or more, particularly preferably 50% or more. Such proportion is less than 100%. The proportion of the thickness of the second region 22 with respect to the total thickness of the first region 21 and the second region 22 is preferably 99% or less, more preferably 80% or less, even more preferably 70% or less, especially preferably 60% or less, particularly preferably 50% or less. In the case where the light-transmitting electroconductive layer 20 includes the first region 21 and the second region 22, these configurations relating to the proportion of the thickness of each of the first region 21 and the second region 22 are preferred in view of achieving both reduction of the compressive residual stress and reduction of the specific resistance of the light-transmitting electroconductive layer 20.

The content ratio of Kr in the first region 21 is preferably 1.0 atomic % or less, more preferably 0.7 atomic % or less, even more preferably 0.5 atomic % or less, even more preferably 0.3 atomic % or less, even more preferably 0.2 atomic % or less, even more preferably less than 0.1 atomic %, entirely in the thickness direction D of the first region 21. This configuration is suitable for achieving the above-described resistance reduction and compressive residual stress reduction in the light-transmitting electroconductive layer 20. The content ratio of Kr in the first region 21 is for example, 0.0001 atomic % or more entirely in the thickness direction D of the first region 21.

The content ratio of Kr in the first region 21 may be non-uniform in the thickness direction D of the first region 21. For example, in the Kr-containing region, the Kr content ratio in the first region 21 may gradually increase or decrease in the thickness direction D depending on the distance from the transparent resin substrate 10. Alternatively, the first region 21 has a partial region on the transparent resin substrate 10 side in which the Kr content ratio gradually increases in the thickness direction D depending on the distance from the transparent resin substrate 10, and a partial region on the opposite side to the transparent resin substrate 10 in which the Kr content ratio gradually decreases in the thickness direction D depending on the distance from the transparent resin substrate 10. Alternatively, the first region 21 has a partial region on the transparent resin substrate 10 side in which the Kr content ratio gradually decreases in the thickness direction D depending on the distance from the transparent resin substrate 10, and a partial region on the opposite side to the transparent resin substrate 10 in which the Kr content ratio gradually increases in the thickness direction D depending on the distance from the transparent resin substrate 10.

The light-transmitting electroconductive layer 20 has a thickness of, for example, 10 nm or more. The light-transmitting electroconductive layer 20 has a thickness of preferably more than 40 nm, more preferably 100 nm or more, even more preferably 110 nm or more, especially preferably 120 nm or more. This configuration is suitable for reducing resistance of the light-transmitting electroconductive layer 20. The light-transmitting electroconductive layer 20 has a thickness of, for example, 1000 nm or less, preferably less than 300 nm, more preferably 250 nm or less, even more preferably 200 nm or less, especially preferably 160 nm or less, particularly preferably less than 150 nm, most preferably 148 nm or less. This configuration is suitable for suppressing warpage of the transparent electroconductive film X.

The light-transmitting electroconductive layer 20 has a surface resistance of, for example, 200Ω/□ or less, preferably 100Ω/□ or less, more preferably 50Ω/□ or less, even more preferably 15Ω/□ or less, especially preferably 15Ω/□ or less, particularly preferably 13Ω/□ or less. The light-transmitting electroconductive layer 20 has a surface resistance of, for example, 1Ω/□ or more. These configurations relating to the surface resistance are suitable for ensuring the low resistance required for the light-transmitting electroconductive layer 20 when the transparent electroconductive film X is provided in a touch sensor device, a light control element, a photoelectric conversion element, a hot wire control member, an antenna member, an electromagnetic wave shielding member, a heater member, an illuminating device, an image display device, or the like. The surface resistance can be measured by a four-terminal method according to JIS K 7194.

The light-transmitting electroconductive layer 20 has a specific resistance of, for example, 2.5×10⁻⁴ Ω·cm or less, preferably less than 2.2×10⁻⁴ Ω·cm, more preferably 2×10⁻⁴ Ω·cm or less, even more preferably 1.9×10⁻⁴ Ω·cm or less, particularly preferably 1.8×10⁻⁴ Ω·cm or less. The light-transmitting electroconductive layer 20 has a specific resistance of preferably 0.1×10⁻⁴ Ω·cm or more, more preferably 0.5×10⁻⁴ Ω·cm or more, even more preferably 1.0×10⁻⁴ Ω·cm or more. These configurations relating to the specific resistance are suitable for ensuring the low resistance required for the light-transmitting electroconductive layer 20 when the transparent electroconductive film X is provided in a touch sensor device, a light control element, a photoelectric conversion element, a hot wire control member, an antenna member, an electromagnetic wave shielding member, a heater member, an illuminating device, an image display device, or the like. The specific resistance is determined by multiplying the surface resistance by the thickness. The specific resistance can be controlled, for example, by adjusting the content ratio of the rare gas atom in the light-transmitting electroconductive layer 20, and by adjusting various conditions at the time when the light-transmitting electroconductive layer 20 is formed by sputtering deposition. Examples of the conditions include a temperature of a base (transparent resin substrate 10 in the present embodiment) where the light-transmitting electroconductive layer 20 is formed by deposition, an amount of oxygen introduced into a film deposition chamber, an atmospheric pressure in the film deposition chamber, and a horizontal magnetic field intensity on a target.

The light-transmitting electroconductive layer 20 has a total light transmittance (JIS K 7375-2008) of preferably 60% or more, more preferably 80% or more, even more preferably 85% or more. This configuration is suitable for ensuring the transparency of the light-transmitting electroconductive layer 20. The light-transmitting electroconductive layer 20 has a total light transmittance of, for example, 100% or less.

Whether the light-transmitting electroconductive layer is crystalline can be judged as follows, for example. First, a light-transmitting electroconductive layer (in the transparent electroconductive film X, the light-transmitting electroconductive layer 20 on the transparent resin substrate 10) is immersed in hydrochloric acid having a concentration of 5% by mass at 20° C. for 15 minutes. Next, the light-transmitting electroconductive layer is washed with water and then dried. Then, in an exposed plane of the light-transmitting electroconductive layer (in the transparent electroconductive film X, a surface of the light-transmitting electroconductive layer 20 opposite to the transparent resin substrate 10), a resistance between a pair of terminals (inter-terminal resistance) at a separation distance of 15 mm is measured. In this measurement, when the inter-terminal resistance is 10 kΩ or less, the light-transmitting electroconductive layer is crystalline. Whether the light-transmitting electroconductive layer is crystalline can be judged by observing the presence of crystal grains in the light-transmitting electroconductive layer in plane view using a transmission electron microscope.

The light-transmitting electroconductive layer 20 has a first compressive residual stress in the first in-plane direction and has a second compressive residual stress less than the first compressive residual stress in the second in-plane direction. That is, in the light-transmitting electroconductive layer 20, the compressive residual stress (second compressive residual stress) in the second in-plane direction orthogonal to the first in-plane direction is less than the compressive residual stress (first compressive residual stress) in at least one direction in the plane thereof (first in-plane direction). In the present embodiment, the first in-plane direction is the MD direction described above, and the second in-plane direction is the TD direction described above (the first in-plane direction is orthogonal to the thickness direction D, and the second in-plane direction is orthogonal to each of the thickness direction D and the first in-plane direction).

The first compressive residual stress is preferably 620 MPa or less, more preferably 600 MPa or less, even more preferably 550 MPa or less. The first compressive residual stress is, for example, 1 MPa or more. The second compressive residual stress is preferably 530 MPa or less, more preferably 500 MPa or less, even more preferably 450 MPa or less, as long as it is less than the first compressive residual stress. The second compressive residual stress is, for example, 1 MPa or more, as long as it is less than the first compressive residual stress. These configurations are suitable for reducing a net internal stress in the light-transmitting electroconductive layer 20. Reduction of the compressive residual stress in the light-transmitting electroconductive layer 20 is suitable for suppressing warpage of the produced transparent electroconductive film X.

A ratio of the second compressive residual stress to the first compressive residual stress is 0.82 or less, preferably 0.8 or less, and the ratio is, for example, 0.1 or more, preferably 0.3 or more, more preferably 0.4 or more. The configuration in which the second compressive residual stress in the second in-plane direction (in the present embodiment, TD direction) is such less than the first compressive residual stress in the first in-plane direction (in the present embodiment, MD direction) serves to achieve high crystal stability.

The transparent electroconductive film X is produced, for example, in the following manner.

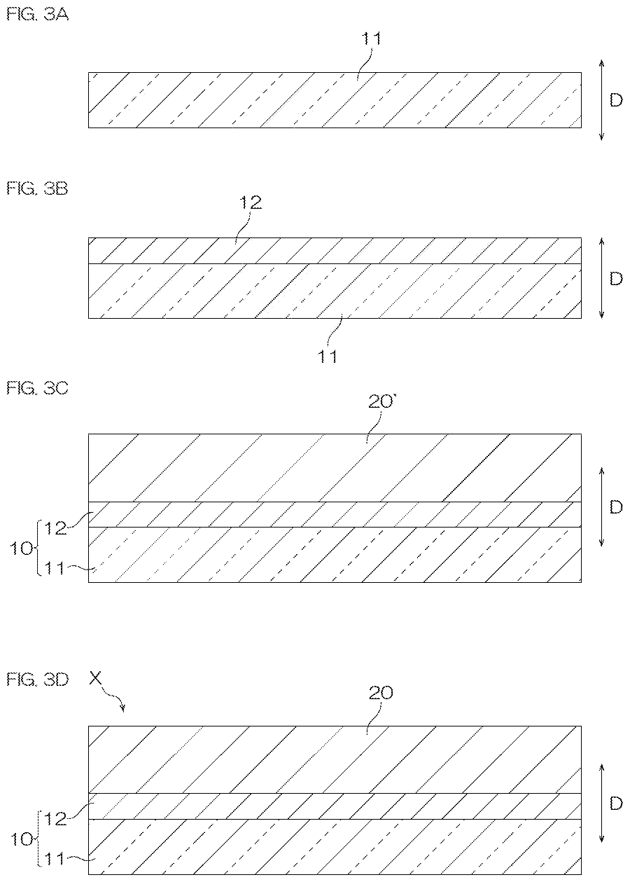

First, as shown in FIG. 3A, a resin film 11 is prepared.

Then, as shown in FIG. 3B, a functional layer 12 is formed on one surface in the thickness direction D of the resin film 11. A transparent resin substrate 10 is prepared by the formation of the functional layer 12 on the resin film 11.

The above-mentioned functional layer 12 as a hard coat layer can be formed by applying a coating of a curable resin composition onto the resin film 11 to form a coated film, and then curing the coated film. When the curable resin composition contains an ultraviolet curing type resin, the coated film is cured by ultraviolet irradiation. When the curable resin composition contains a thermosetting type resin, the coated film is cured by heating.

The exposed surface of the functional layer 12 formed on the resin film 11 is subjected to surface modification treatment as needed. When plasma treatment is performed as the surface modification treatment, argon gas is used for example as an inert gas. In the plasma treatment, discharge electric power is, for example, 10 W or more and for example, 5000 W or less.

Next, as shown in FIG. 3C, an amorphous light-transmitting electroconductive layer 20′ is formed on the transparent resin substrate 10 (film deposition step). Specifically, a film formation material is deposited on the functional layer 12 in the transparent resin substrate 10 by a sputtering method to form an amorphous light-transmitting electroconductive layer 20′. The light-transmitting electroconductive layer 20′ is an amorphous film having both optical transparency and electroconductivity (the light-transmitting electroconductive layer 20′ is converted into a crystalline light-transmitting electroconductive layer 20 by heating in a crystallization step to be described later).

In the sputtering method, a sputtering film formation apparatus capable of conducting a film deposition process in a roll-to-roll process is preferably used. In the production of the transparent electroconductive film X, in the case of using the roll-to-roll type sputtering film formation apparatus, while a long transparent resin substrate 10 is traveled from a supply roll to a take-up roll included in the apparatus, a film formation material is deposited on the transparent resin substrate 10 to form the light-transmitting electroconductive layer 20′. In the sputtering method, a sputtering film formation apparatus having one film deposition chamber may be used, or a sputtering film formation apparatus having a plurality of film deposition chambers sequentially disposed along a travel path of the transparent resin substrate 10 may be used (when the light-transmitting electroconductive layer 20′ including the first region 21 and the second region 22 described above is formed, a sputtering film formation apparatus having two or more film deposition chambers is used).

In the sputtering method, specifically, while a sputtering gas (inert gas) is introduced into a film deposition chamber, which is included in a sputtering film formation apparatus, under vacuum conditions, a negative voltage is applied to a target disposed on a cathode in the film deposition chamber. This generates glow discharge to ionize a gas atom, the gas ion is allowed to collide with the target surface at high speed, a target material is sputtered away from the target surface, and the sputtered target material is deposited on the functional layer 12 of the transparent resin substrate 10.

As the material of the target disposed on the cathode in the film deposition chamber, the electroconductive oxide, described above regarding the light-transmitting electroconductive layer 20, is used, an indium-containing electroconductive oxide is preferably used, and an ITO is more preferably used. When an ITO is used, the ratio of the content of tin oxide to the total content of tin oxide and indium oxide in the ITO, preferably 0.1% by mass or more, more preferably 1% by mass or more, even more preferably 3% by mass or more, further preferably 5% by mass or more, particularly preferably 7% by mass or more, and preferably 15% by mass or less, more preferably 13% by mass or less, even more preferably 12% by mass or less.

The sputtering method is preferably a reactive sputtering method. In the reactive sputtering method, a reactive gas, in addition to the sputtering gas, is introduced into the film deposition chamber.

When the light-transmitting electroconductive layer 20′ containing rare gas atoms is formed entirely over the thickness direction D (in a first case), the gas introduced into one, or two or more film deposition chambers included in the sputtering film formation apparatus contains the sputtering gas and oxygen as the reactive gas. As the sputtering gas, rare gas atoms are preferably used in the present embodiment. As the rare gas atoms, Ar, Kr, and Xe are used, preferably Kr is used. When the sputtering gas contains an inert gas other than Kr, the content ratio thereof is preferably 80% by volume or less, more preferably 50% by volume or less.

When the light-transmitting electroconductive layer 20′ including the first region 21 and the second region 22 described above is formed (in a second case), the gas introduced into a film deposition chamber for forming the first region 21 contains Kr as the sputtering gas and oxygen as the reactive gas. The sputtering gas may contain an inert gas other than Kr. The content ratio of the inert gas other than Kr in the sputtering gas is the same as the above-described content ratio in the first case.

In the above-mentioned second case, the gas introduced into a film deposition chamber for forming the second region 22 contains an inert gas other than Kr as the sputtering gas and oxygen as the reactive gas. As the inert gas other than Kr, Ar and Xe are used, preferably Ar is used.

In the reactive sputtering method, the ratio of the amount of oxygen introduced with respect to the total amount of the sputtering gas and oxygen introduced into the film deposition chamber is, for example, 0.01 flow rate % or more and for example, 15 flow rate % or less.

The atmospheric pressure in the film deposition chamber during film deposition by the sputtering method (sputtering film formation) is, for example, 0.02 Pa or more and for example, 1 Pa or less.

The temperature of the transparent resin substrate 10 during the sputtering film formation is, for example, 100° C. or less. In order to suppress outgassing from the transparent resin substrate 10 or thermal expansion of the transparent resin substrate 10 during the sputtering film formation, the transparent resin substrate 10 is preferably cooled. The outgassing suppression and the thermal expansion suppression serve to achieve high crystal stability of the light-transmitting electroconductive layer 20. From this viewpoint, the temperature of the transparent resin substrate 10 during the sputtering film formation is preferably 20° C. or less, more preferably 10° C. or less, even more preferably 5° C. or less, particularly preferably 0° C. or less, and for example, −50° C. or more, preferably −20° C. or more, more preferably −10° C. or more, even more preferably −7° C. or more.

Examples of a power source for applying a voltage to the target include a DC power source, an AC power source, an MF power source, and an RF power source. As the power source, a DC power source and an RF power source may be used in combination. An absolute value of a discharge voltage during the sputtering film formation is, for example, 50 V or more and for example, 500 V or less.

In the production method, next, as shown in FIG. 3D, the light-transmitting electroconductive layer 20 is converted (crystallized) from amorphous to crystalline by heating (crystallization step). Examples of the heating means include an infrared heater, and an oven, such as a heat-medium heating oven and a hot-air heating oven. The environment during heating may be either a vacuum environment or an atmospheric environment. Preferably, heating is performed in the presence of oxygen. The heating temperature is, for example, 100° C. or more, preferably 120° C. or more, in view of ensuring a high crystallization rate. The heating temperature is, for example, less than 200° C., preferably 180° C. or less, more preferably 170° C. or less, even more preferably 165° C. or less, in view of suppressing the heating effect on the transparent resin substrate 10. The heating time is, for example, 10 hours or less, preferably 200 minutes or less, more preferably 90 minutes or less, even more preferably 60 minutes or less, and for example, 1 minute or more, preferably 5 minutes or more.

After the temperature is returned to room temperature after heating in this step, the transparent resin substrate 10 is shrunk. The configuration in which the light-transmitting electroconductive layer 20 contains Kr is suitable for appropriately shrinking the light-transmitting electroconductive layer 20 on the shrunk transparent resin substrate 10 in the state after the temperature is returned to room temperature (a preferred Kr content ratio in the light-transmitting electroconductive layer 20 is as described above). The shrinkage of the light-transmitting electroconductive layer 20 after the temperature is returned to room temperature helps reduce the compressive residual stress in the light-transmitting electroconductive layer 20.

As described above, the transparent electroconductive film X is produced.

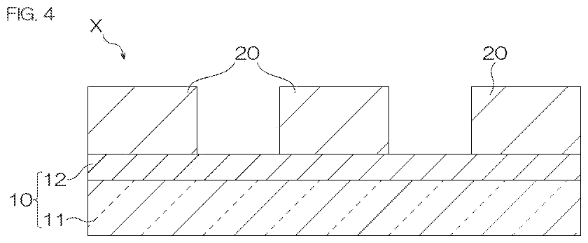

The light-transmitting electroconductive layer 20 of the transparent electroconductive film X may be patterned as schematically shown in FIG. 4. The light-transmitting electroconductive layer 20 can be patterned by etching the light-transmitting electroconductive layer 20 through a predetermined etching mask. The patterning of the light-transmitting electroconductive layer 20 may be performed before the crystallization step described above or after the crystallization step. The patterned light-transmitting electroconductive layer 20 functions as a wiring pattern, for example.

In the transparent electroconductive film X, as described above, the light-transmitting electroconductive layer 20 on the transparent resin substrate 10 has the first compressive residual stress in the first in-plane direction, and the second compressive residual stress less than the first compressive residual stress in the second in-plane direction (orthogonal to the first in-plane direction), and the ratio of the second compressive residual stress to the first compressive residual stress is 0.82 or less, preferably 0.8 or less. This configuration is suitable for achieving high crystal stability of the light-transmitting electroconductive layer 20. That is, in the transparent electroconductive film X, the configuration in which the second compressive residual stress in the second in-plane direction is such less than the first compressive residual stress in the first in-plane direction is suitable for suppressing after-the-fact changes in the resistance value of the light-transmitting electroconductive layer 20 even in the transparent electroconductive film X in which a crystalline light-transmitting electroconductive layer 20 is formed through the crystallization process at relatively low temperature as described above. Examples and Comparative Examples below specifically show these facts.

In the transparent electroconductive film X, the functional layer 12 may be an adhesion improving layer for achieving high adhesion of the light-transmitting electroconductive layer 20 to the transparent resin substrate 10. The configuration in which the functional layer 12 is an adhesion improving layer is suitable for ensuring an adhesive force between the transparent resin substrate 10 and the light-transmitting electroconductive layer 20.

The functional layer 12 may be an index-matching layer for adjusting a reflection coefficient of the surface (one surface in the thickness direction D) of the transparent resin substrate 10. When the light-transmitting electroconductive layer 20 is patterned on the transparent resin substrate 10, the configuration in which the functional layer 12 is an index-matching layer is suitable for making it difficult to visually recognize the pattern shape of the light-transmitting electroconductive layer 20.

The functional layer 12 may be a peel functional layer for allowing the light-transmitting electroconductive layer 20 to be practically peeled off from the transparent resin substrate 10. The configuration in which the functional layer 12 is a peel functional layer is suitable for peeling off the light-transmitting electroconductive layer 20 from the transparent resin substrate 10 and transferring the light-transmitting electroconductive layer 20 to another member.

The functional layer 12 may be a composite layer in which a plurality of layers are continuous in the thickness direction D. The composite layer preferably includes two or more layers selected from the group consisting of a hard coat layer, an adhesion improving layer, an index-matching layer, and a peel functional layer. This configuration is suitable for exhibiting the above-described functions of the selected layers in the functional layer 12 in a composite manner. In a preferred embodiment, the functional layer 12 includes an adhesion improving layer, a hard coat layer, an index-matching layer in this order toward one side in the thickness direction D on the resin film 11. In another preferred embodiment, the functional layer 12 includes a peel functional layer, a hard coat layer, an index-matching layer in this order toward one side in the thickness direction D on the resin film 11.

The transparent electroconductive film X is used in a state where the film X is fixed to an article and the light-transmitting electroconductive layer 20 is patterned as needed. The transparent electroconductive film X is bonded to an article, for example, with a fixing functional layer interposed therebetween. In one embodiment of the present invention, the transparent resin substrate 10 of the transparent electroconductive film X is not adjacent to a glass substrate, but a fixing functional layer such as an adhesive or a bonding agent may be interposed between the transparent resin substrate 10 and the glass substrate.

Examples of the article include an element, a member, and a device. That is, examples of the article with the transparent electroconductive film include an element with a transparent electroconductive film, a member with a transparent electroconductive film, and a device with a transparent electroconductive film.

Examples of the element include a light control element and a photoelectric conversion element. Examples of the light control element include a current driven-type light control element and an electric field driven-type light control element. Examples of the current driven-type light control element include an electrochromic (EC) light control element. Examples of the electric field driven-type light control element include a polymer dispersed liquid crystal (PDLC) light control element, a polymer network liquid crystal (PNLC) light control element, and a suspended particle device (SPD) light control element. Example of the photoelectric conversion element include a solar cell. Examples of the solar cell include an organic thin film solar cell and a dye-sensitized solar cell. Examples of the member include an electromagnetic wave shielding member, a hot wire control member, a heater member, and an antenna member. Examples of the device include a touch sensor device, an illuminating device, and an image display device.

The articles with the transparent electroconductive film are suitable for exhibiting stable properties in the light-transmitting electroconductive layer 20 because the light-transmitting electroconductive layer 20 of the transparent electroconductive film X included in each of the articles is suitable for achieving high crystal stability.

Examples of the fixing functional layer described above include an adhesive layer and a bonding layer. As a material of the fixing functional layer, any material can be used without particular limitation as long as it has transparency and exhibits the fixing function. The fixing functional layer is preferably formed of resin. Examples of the resin include acrylic resin, silicone resin, polyester resin, polyurethane resin, polyamide resin, polyvinyl ether resin, vinyl acetate/vinyl chloride copolymer, modified polyolefin resin, epoxy resin, fluorine resin, natural rubber, and synthetic rubber. As the above-mentioned resin, acrylic resin is preferred because it shows adhesive properties such as cohesiveness, tackiness, and moderate wettability; excellent in transparency; and excellent in weather resistance and heat resistance.

The fixing functional layer (fixing functional layer forming resin) may be mixed with a corrosion inhibitor in order to inhibit corrosion of the light-transmitting electroconductive layer 20. The fixing functional layer (fixing functional layer forming resin) may be mixed with a migration inhibitor (e.g., material disclosed in Japanese Unexamined Patent Publication No. 2015-022397) in order to inhibit migration of the light-transmitting electroconductive layer 20. The fixing functional layer (fixing functional layer forming resin) may also be mixed with an ultraviolet absorber in order to suppress deterioration of the article when used outdoors. Examples of the ultraviolet absorber include a benzophenone compound, a benzotriazole compound, a salicylic acid compound, an anilide oxalate compound, a cyanoacrylate compound, and a triazine compound.

When the transparent resin substrate 10 of the transparent electroconductive film X is fixed to the article with the fixing functional layer interposed therebetween, the light-transmitting electroconductive layer 20 (including the patterned light-transmitting electroconductive layer 20) is exposed in the transparent electroconductive film X. In this case, a cover layer may be disposed on the exposed surface of the light-transmitting electroconductive layer 20. The cover layer is a layer that covers the light-transmitting electroconductive layer 20, and can improve reliability of the light-transmitting electroconductive layer 20 and suppress functional deterioration due to damage of the light-transmitting electroconductive layer 20. Such a cover layer is preferably formed of a dielectric material, more preferably a composite material of a resin and an inorganic material. Examples of the resin include the above-mentioned resins for the fixing functional layer. Examples of the inorganic material include inorganic oxide and fluoride. Examples of the inorganic oxide include silicon oxide, titanium oxide, niobium oxide, aluminum oxide, zirconium dioxide, and calcium oxide. Examples of the fluoride includes magnesium fluoride. The cover layer (mixture of the resin and the inorganic material) may be mixed with the corrosion inhibitor, migration inhibitor, and ultraviolet absorber described above.

### EXAMPLES

In the following, the present invention will be described specifically based on Examples. The present invention is not limited by Examples. The specific numeral values described below, such as mixing ratios (contents), physical property values, and parameters can be replaced with the corresponding mixing ratios (contents), physical property values, and parameters in the above-described “DESCRIPTION OF THE EMBODIMENTS”, including the upper limit values (numeral values defined with “or less”, and “less than”) or the lower limit values (numeral values defined with “or more”, and “more than”).

### Example 1

An ultraviolet curable resin containing acrylic resin was applied to one surface of a long PET film (50 μm thick, manufactured by Toray Industries, Inc.) as a resin film to form a coated film. Subsequently, the coated film was cured by ultraviolet irradiation to form a hard coat layer (2 μm thick). In this manner, a transparent resin substrate including the resin film and the hard coat layer as a functional layer was prepared (after the transparent substrate was subjected to heating treatment at 165° C. for 1 hour, the transparent resin substrate had a thermal shrinkage coefficient in the most shrinkable direction (maximum thermal shrinkage coefficient; in this Example, a thermal shrinkage coefficient in the MD direction) of 0.63%).

Next, an amorphous light-transmitting electroconductive layer having a thickness of 130 nm was formed on the hard coat layer of the transparent resin substrate by a reactive sputtering method (film deposition step). In the reactive sputtering method, a sputtering film formation apparatus (DC magnetron sputtering apparatus) capable of conducting a film deposition process in a roll-to-roll system was used. Sputtering film formation conditions in this Example are as follows.

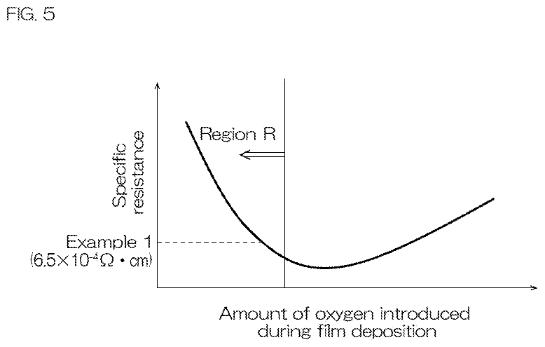

As a target, a sintered body of indium oxide and tin oxide (with a tin oxide concentration of 10% by mass) was used. As a power source for applying a voltage to the target, a DC power source was used. A horizontal magnetic field intensity on the target was 90 mT. A film deposition temperature (temperature of the transparent resin substrate having the light-transmitting electroconductive layer laminated thereon) was −5° C. A film deposition chamber included in the apparatus was vacuum-evacuated internally to an ultimate degree of vacuum of 0.8×10⁻⁴ Pa, and Kr as a sputtering gas and oxygen as a reactive gas were then introduced into the film deposition chamber, so that the atmospheric pressure in the film deposition chamber was 0.2 Pa. A ratio of an amount of oxygen introduced with respect to the total amount of Kr and oxygen introduced into the film deposition chamber was about 2.5 flow rate %, and the amount of oxygen introduced was within a region R of a specific resistance-oxygen introduced amount curve as shown in FIG. 5, and was adjusted so that a formed film had a specific resistance value of 6.5×10⁻⁴ Ω·cm. The specific resistance-oxygen introduced amount curve shown in FIG. 5 can be previously prepared by investigating the dependence of the specific resistance of the light-transmitting electroconductive layer on the amount of oxygen introduced when the light-transmitting electroconductive layer is formed by the reactive sputtering method under the same conditions as above other than the amount of oxygen introduced.

Next, the light-transmitting electroconductive layer on the transparent resin substrate was crystallized by heating in a hot-air oven (crystallization step). In this step, the heating temperature was 165° C. and the heating time was 1 hour.

As described above, a transparent electroconductive film of Example 1 was prepared. The light-transmitting electroconductive layer (130 nm thick, crystalline) of the transparent electroconductive film of Example 1 was made of a single Kr-containing ITO layer.

### Example 2

A transparent electroconductive film of Example 2 was prepared in the same manner as the transparent electroconductive film of Example 1 except that the film deposition conditions in the film deposition step were partially changed, and that the heating conditions in the crystallization step were changed. In the film deposition step of this Example, the atmospheric pressure in the film deposition chamber was 0.4 Pa, and the thickness of the formed light-transmitting electroconductive layer was 160 nm. In the crystallization step of this Example, the heating temperature was 155° C. and the heating time was 2 hours.

The light-transmitting electroconductive layer (160 nm thick, crystalline) of the transparent electroconductive film of Example 2 was made of a single Kr-containing ITO layer.

### Example 3

A transparent electroconductive film of Example 3 was prepared in the same manner as the transparent electroconductive film of Example 1 except that in the film deposition step, first sputtering film formation in which a first region (50 nm thick) of the light-transmitting electroconductive layer was formed on the transparent resin substrate and second sputtering film formation in which a second region (80 nm thick) of the light-transmitting electroconductive layer was formed on the first region were sequentially performed.

The first sputtering film formation conditions in this Example are as follows. As the target, a sintered body of indium oxide and tin oxide (with a tin oxide concentration of 10% by mass) was used. As a power source for applying a voltage to the target, a DC power source was used. A horizontal magnetic field intensity on the target was 90 mT. The film deposition temperature was −5° C. A first film deposition chamber included in the apparatus was vacuum-evacuated internally to an ultimate degree of vacuum of 0.8×10⁻⁴ Pa, and Kr as the sputtering gas and oxygen as the reactive gas were then introduced into the first film deposition chamber, so that the atmospheric pressure in the film deposition chamber was 0.2 Pa. The amount of oxygen introduced into the film deposition chamber was adjusted so that the formed film had a specific resistance value of 6.5×10⁻⁴ Ω·cm.

The second sputtering film formation conditions in this Example are as follows. A second film deposition chamber included in the apparatus was vacuum-evacuated internally to an ultimate degree of vacuum of 0.8×10⁻⁴ Pa, and Ar as the sputtering gas and oxygen as the reactive gas were then introduced into the second film deposition chamber, so that the atmospheric pressure in the film deposition chamber was 0.4 Pa. In this Example, the other conditions in the second sputtering film formation were the same as those in the first sputtering film formation.

As described above, the transparent electroconductive film of Example 3 was prepared. The light-transmitting electroconductive layer (130 nm thick, crystalline) of the transparent electroconductive film of Example 3 had a first region (50 nm thick) made of a Kr-containing ITO layer and a second region (80 nm thick) made of an Ar-containing ITO layer in order from the transparent resin substrate side.

### Examples 4 to 6

A transparent electroconductive film of each of Examples 4 to 6 was prepared in the same manner as the transparent electroconductive film of Example 3 except that in the light-transmitting electroconductive layer formed in the film deposition step, the thickness of the first region was 66 nm (Example 4), 85 nm (Example 5), or 87 nm (Example 6) instead of 50 nm, and the thickness of the second region was 64 nm (Example 4), 45 nm (Example 5), or 38 nm (Example 6) instead of 80 nm.

The light-transmitting electroconductive layer (130 nm thick, crystalline) of the transparent electroconductive film of Example 4 had a first region (66 nm thick) made of a Kr-containing ITO layer and a second region (64 nm thick) made of an Ar-containing ITO layer in order from the transparent resin substrate side. The light-transmitting electroconductive layer (130 nm thick) of the transparent electroconductive film of Example 5 had a first region (85 nm thick) made of a Kr-containing ITO layer and a second region (45 nm thick) made of an Ar-containing ITO layer in order from the transparent resin substrate side. The light-transmitting electroconductive layer (125 nm thick) of the transparent electroconductive film of Example 6 had a first region (87 nm thick) made of a Kr-containing ITO layer and a second region (38 nm thick) made of an Ar-containing ITO layer in order from the transparent resin substrate side.

### Example 7

A transparent electroconductive film of Example 7 was prepared in the same manner as the transparent electroconductive film of Example 1 except the following in the sputtering film formation. As the sputtering gas, a gas mixture of krypton and argon (90% by volume of Kr, 10% by volume of Ar) was used. The atmospheric pressure in the film deposition chamber was 0.2 Pa. The ratio of the amount of oxygen introduced with respect to the total amount of the gas mixture and oxygen introduced into the film deposition chamber was about 2.7 flow rate %, and the amount of oxygen introduced was adjusted so that the formed film had a specific resistance value of 5.7×10⁻⁴ Ω·cm.

The light-transmitting electroconductive layer (130 nm thick, crystalline) of the transparent electroconductive film of Example 7 was made of a single ITO layer containing Kr and Ar.

### Comparative Example 1

A transparent electroconductive film of Comparative Example 1 was prepared in the same manner as the transparent electroconductive film of Example 1 except that in the film deposition step, Ar was used as the sputtering gas instead of Kr, and the film deposition pressure was 0.4 Pa instead of 0.2 Pa. The light-transmitting electroconductive layer (130 nm thick, crystalline) of the transparent electroconductive film of Comparative Example 1 was made of a single Ar-containing ITO layer.

### Comparative Example 2

A transparent electroconductive film of Comparative Example 2 was prepared in the same manner as the transparent electroconductive film of Example 2 except that in the film deposition step, Ar was used as the sputtering gas instead of Kr, and the film deposition pressure was 0.4 Pa instead of 0.2 Pa, and in the crystallization step, first heating treatment was performed at 170° C. for 5 minutes and then second heating treatment was performed at 165° C. for 1 hour, instead of heating treatment at 165° C. for 1 hour. The light-transmitting electroconductive layer (160 nm thick, crystalline) of the transparent electroconductive film of Comparative Example 2 was made of a single Ar-containing ITO layer.

### <Thickness of Light-Transmitting Electroconductive Layer>

The thickness of the light-transmitting electroconductive layer of each of the transparent electroconductive films of Examples 1 to 7 and Comparative Examples 1 and 2 was measured by FE-TEM observation. Specifically, first, a sample for cross-section observation of each of the light-transmitting electroconductive layers in Examples 1 to 7 and Comparative Examples 1 and 2 was prepared by an FIB micro-sampling method. In the FIB micro-sampling method, an FIB device (trade name “FB2200” manufactured by Hitachi Ltd.) was used and the accelerating voltage was set to 10 kV. Next, the thickness of the light-transmitting electroconductive layer in the sample for cross-section observation was measured by FE-TEM observation. In the FE-TEM observation, an FE-TEM device (trade name “JEM-2800” manufactured by JEOL Ltd.) was used, and the accelerating voltage was set to 200 kV.

Regarding Examples 3 to 6, a sample for cross-section observation was prepared from an intermediate prepared before the second region was formed on the first region, and the thickness of the first region of each of the light-transmitting electroconductive layers in Examples 3 to 6 was measured by the FE-TEM observation of the sample. The thickness of the second region of each of the light-transmitting electroconductive layers in Examples 3 to 6 was determined by subtracting the thickness of the first region from the total thickness of each of the light-transmitting electroconductive layers in Examples 3 to 6. A percentage of the first region of the light-transmitting electroconductive layer in the thickness direction was 38.5% in Example 3, 50.8% in Example 4, 65.4% in Example 5, and 69.6% in Example 6.

### <Specific Resistance>

In each of the transparent electroconductive films of Examples 1 to 7 and Comparative Examples 1 and 2, the specific resistance of the light-transmitting electroconductive layer was determined. Specifically, a surface resistance of the light-transmitting electroconductive layer was measured by a four-terminal method according to JIS K 7194 (1994), and the specific resistance (Ω·cm) was then determined by multiplying the surface resistance value by the thickness of the light-transmitting electroconductive layer. The results are shown in Table 1.

### <Quantitative Analysis of Rare Gas Atoms in Light-Transmitting Electroconductive Layer>

The contents of Kr and Ar atoms in the light-transmitting electroconductive layer of each of the transparent electroconductive films of Examples 1 to 7 and Comparative Examples 1 and 2 were analyzed by Rutherford backscattering spectrometry (RBS). The ratios of five elements including In+Sn (in RBS, it was difficult to measure In and Sn separately, so that the two elements were evaluated in combination), O, Ar, and Kr, which were detected elements, were determined to thereby determine the amounts (atomic %) of the Kr atom and the Ar atom present in the light-transmitting electroconductive layer. The use device and the measurement conditions are as follows. As the analysis results, the Kr content (atomic %), the Ar content (atomic %), and the rare gas atom content (atomic %) are shown in Table 1. For the analysis of the Kr content, a certain measurement value of not less than the detection limit value (lower limit) failed to be obtained in Examples 1 to 7 (the detection limit value may vary depending on the thickness of the light-transmitting electroconductive layer to be measured). Therefore, in Table 1, the Kr content in the light-transmitting electroconductive layer is denoted as “<a specific detection limit value in the thickness of the measured light-transmitting electroconductive layer” in order to indicate that it is below the detection limit value in the thickness of such layer (the same notation is used for the rare gas atom content).

### <Use Device>

Pelletron 3SDH (manufactured by National Electrostatics Corporation)

### <Measurement Conditions>

Incident ion: ⁴He⁺⁺

Incident energy: 2300 keV

Incident angle: 0 deg.

Scattering angle: 160 deg.

Sample current: 6 nA

Beam diameter: 2 mmφ

In-plane rotation: Nil

Irradiation dose: 75 μC

### <Confirmation of Kr Atoms in Light-Transmitting Electroconductive Layer>

Whether each of the light-transmitting electroconductive layers in Examples 1 to 7 contained Kr atoms was confirmed as follows. First, using a scanning X-ray fluorescence spectrometer (trade name “ZSX Primus IV” manufactured by Rigaku Corporation), X-ray fluorescence analysis measurement was repeated 5 times under the following measurement conditions, an average value of the scan angles was calculated, and an X-ray spectrum was generated. It was then confirmed that a peak appeared near a scan angle of 28.2° in the generated X-ray spectrum, thereby confirming that Kr atoms were contained in the light-transmitting electroconductive layer.

### <Measurement Conditions>

Spectrum: Kr-KA

Measurement diameter: 30 mm

Atmosphere: Vacuum

Target: Rh

Tube voltage: 50 kV

Tube current: 60 mA

Primary filter: Ni40

Scan angle (deg.): 27.0 to 29.5

Step (deg.): 0.020

Speed (deg/min): 0.75

Attenuator: 1/1

Slit: S2

Analyzing crystal: LiF (200)

Detector: SC

PHA: 100 to 300

### <Compressive Residual Stress in Light-Transmitting Electroconductive Layer>

The compressive residual stress in the light-transmitting electroconductive layer (crystalline ITO film) of each of the transparent electroconductive films of Examples 1 to 7 and Comparative Examples 1 and 2 was indirectly determined from a crystal lattice strain of the light-transmitting electroconductive layer. Specific details are as follows.

First, a rectangular measuring sample (50 mm×50 mm) was cut out from the transparent electroconductive film. Then, using a powder X-ray diffractometer (trade name “SmartLab”, manufactured by Rigaku Corporation), diffracted intensities of the measuring sample were measured at intervals of 0.02° within a range of measurement scattering angle 2θ=60 to 61.6° (0.15°/min). Subsequently, a crystal lattice spacing d of the light-transmitting electroconductive layer in the measuring sample was calculated based on a peak (peak of the (622) plane of ITO) angle 2θ of the obtained diffraction image and a wavelength λ of an X-ray source, and a lattice strain ε was calculated based on d. For the calculation of d, the following equation (1) was used, and for the calculation of ε, the following equation (2) was used.

[Mathematical Formula 1]

2d sin θ=λ (1)

ε=(d−d₀)/d₀ (2)

In equations (1) and (2), λ is a wavelength (=0.15418 nm) of the X-ray source (Cu Kα ray), and do is a lattice plane spacing (=0.1518967 nm) of ITO in a stress-free state. The above-mentioned X-ray diffraction measurement was performed for each of angles Ψ of 65°, 70°, 75°, and 85° formed by a film plane-normal and an ITO lattice plane-normal, and a lattice strain E at each angle Ψ was calculated. The angle Ψ formed by the film plane-normal and the ITO lattice plane-normal was adjusted by rotating a sample with a TD direction (direction orthogonal to the MD direction in plane) of the transparent resin substrate in the measuring sample (a part of the transparent electroconductive film) as a rotation axis center (adjustment of angle Ψ). A residual stress σ in the ITO film in-plane direction was determined by the following equation (3) from the slope of a line obtained by plotting a relationship between Sin² Ψ and the lattice strain ε. The determined residual stresses σ are shown in Table 1 as a first compressive residual stress S₁ (MPa) in the MD direction.

$$\begin{matrix}[ Mathematical Formula 2 ] & \\ ε = \frac{1 + v}{E} σ {sin}^{2} Ψ - \frac{2 v}{E} σ & ( 3 )\end{matrix}$$

In equation (3), E was a Young's modulus (=115 GPa) of ITO, and v was a Poisson's ratio (=0.35) of ITO.

A second compressive residual stress S₂ (MPa) in the TD direction was derived in the same manner as the first compressive residual stress Si, except that the above-mentioned adjustment of angle Ψ in the X-ray diffraction measurement was performed by rotating the sample with the MD direction (direction orthogonal to the TD direction in plane) as the rotation axis center, instead of the TD direction of the transparent resin substrate in the measuring sample. The resulting values are shown in Table 1. Ratios (S₂/S₁) of the second compressive residual stress S₂ to the first compressive residual stress S₁ are also shown in Table 1.

### <Crystal Stability>

In each of the transparent electroconductive films of Examples 1 to 7 and Comparative Examples 1 and 2, the crystal stability of the light-transmitting electroconductive layer was determined. Specifically, first, a first surface resistance R₁ (surface resistance before heating treatment) of the light-transmitting electroconductive layer of the transparent electroconductive film was measured by a four-terminal method according to JIS K 7194 (1994). Then, the transparent electroconductive film was subjected to heating treatment. In the heating treatment, the heating temperature was 175° C. and the heating time was 1 hour. Next, a second surface resistance R₂ (surface resistance after heating treatment) of the light-transmitting electroconductive layer of the transparent electroconductive film was measured by the four-terminal method according to JIS K 7194 (1994). A ratio of the second surface resistance R₂ to the first surface resistance R₁ (R₂/R₁) was then determined. The resulting values are shown in Table 1. It shows that the closer to 1 the R₂/R₁ value is, the less the resistance value of the light-transmitting electroconductive layer varies due to the heating treatment, and therefore, it shows high crystal stability of such layer.

TABLE 1

| | | | | | Film deposition | | | | | | |
|---|---|---|---|---|---|---|---|---|---|---|---|
| | | | | | conditions | | | | | | |
| | Light-transmitting electroconductive layer | | | | Atmo- | | | Compressive | | | |
| | | Kr | Ar | Rare gas | spheric | Temper- | Specific | residual stress | | | Crystal |
| | Thickness | content | content | atom content | pressure | ature | resistance | S₁ [MD] | S₂ [TD] | | stability |
| | (nm) | (atomic %) | (atomic %) | (atomic %) | (Pa) | (° C.) | (Ω · cm) | (MPa) | (MPa) | S₂/S₁ | (R₂/R₁) |
| Ex. 1 | 130 | <0.18 | — | <0.18 | 0.2 | −5 | 1.6 × 10⁻⁴ | 395 | 147 | 0.37 | 0.97 |
| Ex. 2 | 160 | <0.20 | — | <0.20 | 0.4 | −5 | 1.6 × 10⁻⁴ | 296 | 123 | 0.42 | 0.95 |
| Ex. 3 | 80 [Second region] | — | 0.14 | <0.32 | 0.4 | −5 | 1.6 × 10⁻⁴ | 600 | 480 | 0.80 | 0.96 |
| | 50 [First region] | <0.18 | — | | 0.2 | −5 | | | | | |
| Ex. 4 | 64 [Second region] | — | 0.14 | <0.32 | 0.4 | −5 | 1.5 × 10⁻⁴ | 515 | 392 | 0.76 | 0.96 |
| | 66 [First region] | <0.18 | — | | 0.2 | −5 | | | | | |
| Ex. 5 | 45 [Second region] | — | 0.14 | <0.32 | 0.4 | −5 | 1.4 × 10⁻⁴ | 463 | 285 | 0.62 | 0.96 |
| | 85 [First region] | <0.18 | — | | 0.2 | −5 | | | | | |
| Ex. 6 | 38 [Second region] | — | 0.14 | <0.32 | 0.4 | −5 | 1.5 × 10⁻⁴ | 539 | 290 | 0.54 | 0.97 |
| | 87 [First region] | <0.18 | — | | 0.2 | −5 | | | | | |
| Ex. 7 | 130 | <0.18 | 0.04 | <0.22 | 0.2 | −5 | 1.6 × 10⁻⁴ | 434 | 256 | 0.59 | 0.95 |
| Comp. | 130 | — | 0.14 | 0.14 | 0.4 | −5 | 2.3 × 10⁻⁴ | 630 | 560 | 0.89 | 0.89 |
| Ex. 1 | | | | | | | | | | | |
| Comp. | 160 | — | 0.14 | 0.14 | 0.4 | −5 | 2.2 × 10⁻⁴ | 780 | 650 | 0.83 | 0.91 |
| Ex. 2 | | | | | | | | | | | |

### INDUSTRIAL APPLICABILITY

The transparent electroconductive film of the present invention can be used as, for example, a supply of a conductor film for forming a pattern of a transparent electrode in various devices such as a liquid crystal display, a touch panel, and an optical sensor.

### DESCRIPTION OF REFERENCE NUMERALS

X transparent electroconductive film
D thickness direction
10 transparent resin substrate
11 resin film
12 functional layer
20 light-transmitting electroconductive layer
21 first region
22 second region

1. A transparent electroconductive film, comprising:
a transparent resin substrate and a light-transmitting electroconductive layer in this order in a thickness direction,
wherein the light-transmitting electroconductive layer has a first compressive residual stress in a first in-plane direction orthogonal to the thickness direction, and has a second compressive residual stress less than the first compressive residual stress in a second in-plane direction orthogonal to each of the thickness direction and the first in-plane direction, and
a ratio of the second compressive residual stress to the first compressive residual stress is 0.82 or less.

2. The transparent electroconductive film according to claim 1, wherein the light-transmitting electroconductive layer contains krypton.

3. The transparent electroconductive film according to claim 1, wherein the transparent resin substrate is not adjacent to a glass substrate.

4. The transparent electroconductive film according to claim 1, wherein the light-transmitting electroconductive layer has a specific resistance of less than 2.2×10⁻⁴ Ω·cm.

5. The transparent electroconductive film according to claim 1, wherein the light-transmitting electroconductive layer has a thickness of 100 nm or more.
